(19) United States
(12) Patent Application Publication
(10) Pub. No.: US 2015/0375275 A1
(43) Pub. Date: Dec. 31, 2015

(54) UV-ASSISTED REMOVAL OF METAL OXIDES IN AN AMMONIA-CONTAINING ATMOSPHERE

(71) Applicant: APPLIED MATERIALS, INC., Santa Clara, CA (US)

(72) Inventors: Kelvin CHAN, San Ramon, CA (US); Alexandros T. DEMOS, Fremont, CA (US)

(21) Appl. No.: 14/758,760

(22) PCT Filed: Jan. 31, 2014
(86) PCT No.: PCT/US14/14277

§ 371 Date: Jun. 30, 2015

Related U.S. Application Data
(60) Provisional application No. 61/783,336, filed on Mar. 14, 2013.

(51) Int. Cl. B08B 7/00; H01L 21/02

(52) U.S. Cl. CPC B08B 7/0057; H01L 21/02057

(57) ABSTRACT

A method for removing copper oxides from a substrate with one or more copper features is disclosed herein. The method can include positioning a substrate comprising one or more copper and dielectric containing structures in a processing chamber delivering a cleaning gas comprising ammonia to the processing chamber; and exposing the copper and dielectric containing structure to the cleaning gas and ultraviolet (UV) radiation concurrently.

### BACKGROUND OF THE INVENTION

1. Field of the Invention

Embodiments described herein generally relate to a removal of oxides from metal surfaces. More specifically, embodiments described herein generally relate to removal of copper oxide (CuO) after chemical mechanical polishing (CMP) in back end of line (BEOL) integration.

2. Description of the Related Art

The dielectric constant (k) of interlayer dielectric (ILD) films is continually decreasing as device scaling continues. Minimizing integration damage on low dielectric constant (low-k) films is important to be able to continue decreasing feature sizes. However, as feature sizes shrink, improvement in the resistive capacitance and reliability of ILD films becomes a serious challenge.

Current techniques for the removal of copper oxides (CuO) and chemical mechanical planarization (CMP) residues involve the use of ammonia (NH₃) or hydrogen (H₂) plasmas. Removal of the copper oxides and CMP residues are necessary to improve the electromigration (EM) of the metallization structures and the time dependent dielectric breakdown (TDDB) of the ILD films. Also, leftover copper oxides and CMP residues can reduce adhesion to subsequently formed layers. However, exposing low-k films to NH₃ and H₂ plasmas modifies the ILD film and increases the k value.

Thus, a improved methods for the removal of copper oxides and CMP residues are desirable to minimize the k value increase of low-k films.

### SUMMARY OF THE INVENTION

The embodiments described herein generally relate to removal of copper oxide (CuO) after chemical mechanical polishing (CMP) in back end of line (BEOL) integration.

In one embodiment, a method for removing copper oxides can include positioning a substrate comprising one or more copper and dielectric containing structures in a processing chamber, delivering a cleaning gas comprising ammonia to the processing chamber and exposing the copper and dielectric containing structure to the cleaning gas and ultraviolet (UV) radiation concurrently.

In another embodiment, a method for removing copper oxides can include planarizing the substrate comprising one or more copper and dielectric containing structures using chemical mechanical polishing, positioning a substrate comprising one or more copper and dielectric containing structures in a processing chamber, maintaining the substrate at a temperature between 200° C. and 400° C., delivering a cleaning gas comprising ammonia to the processing chamber, equilibrating the cleaning gas in the processing chamber and exposing the copper and dielectric containing structure to the cleaning gas and ultraviolet (UV) radiation concurrently, wherein the wavelength is between 180 nm and 200 nm.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates a cross-sectional view of one embodiment of a device structure 100 after being planarized by a CMP process;

FIG. 2 is a flow diagram of a method for removing copper oxides according to one embodiment;

FIG. 3 is a chart depicting copper removal based on reflectivity for a substrate processed according to one or more embodiments;

FIG. 4 is a chart depicting damage to the dielectric structure during copper removal for a substrate processed according to one or more embodiments;

FIG. 5 is a chart depicting the etch rate of a carbon containing layer for a substrate processed according to one or more embodiments;

FIG. 6 is a chart depicting copper oxide removal based on reflectivity for a substrate processed according to one or more embodiments; and

FIG. 7 is a chart depicting copper oxide removal based on reflectivity for a substrate processed according to one or more embodiments.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments disclosed herein generally provide methods for the removal of copper oxides during semiconductor fabrication. Embodiments disclosed herein also provide methods for the removal of byproducts formed during chemical mechanical planarization (CMP). Such byproducts include copper oxides formed on the metallization structures and residues from OMP processes, such as electrolyte slurry compounds. By placing the post-CMP wafer in a chamber with a UV source, delivering a source gas with one or more NH bonds to the chamber, activating the source gas

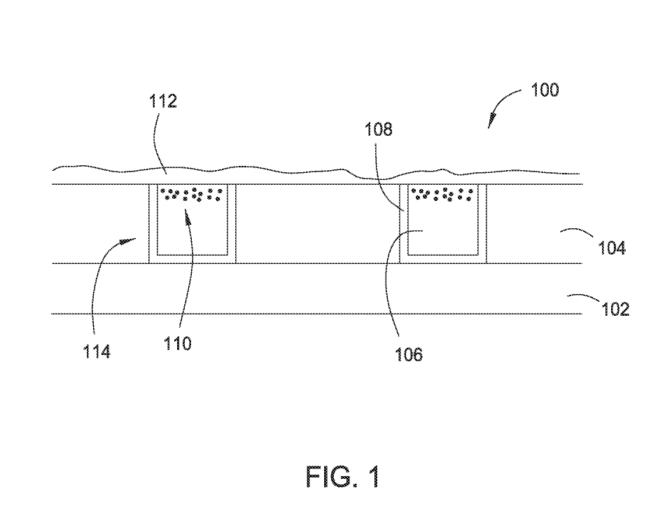

FIG. 1 illustrates a cross-sectional view of one embodiment of a device structure 100 after being planarized by a CMP process. The device structure 100 may be an interconnect structure for a semiconductor chip. The structure 100 generally includes a substrate 102, an interlayer dielectric (ILD) 104, and copper material 106 formed in features 114 of the interlayer dielectric 104. The structure 100 may be created by depositing the interlayer dielectric 104 onto the substrate 102 in a continuous layer, etching the interlayer dielectric 104 to form the features 114 therein, depositing a diffusion barrier 108 into the features 114 of the interlayer dielectric 104, and depositing the copper material 106 into the features 114 of the interlayer dielectric 104. The interlayer dielectric 104 may be formed from a low-k material such as silicon oxide, silicon oxynitride, silicon carbon oxide, silicon carbon nitride, or other suitable materials. The term “low k material” generally refers to materials having a dielectric constant that is generally less than about 3.9. More typically, for the advanced design rules, the dielectric constants of the low k materials are selected to be less than 3.0, and oftentimes less than 2.5. The interlayer dielectric 104 may have a k value of 5 or less, such as 3 or less. The copper material 106 may be high purity copper or a copper alloy, such as copper-aluminum, copper-manganese, or other related alloys. The diffusion barrier 108 may be formed from, for example, Ta/TaN, TiN/Ti, or other suitable materials.

Excess copper material may be deposited outside the features 114 of the interlayer dielectric 104. To remove the excess copper material, and to make the thickness of the structure 100 even, a CMP process may be used. The CMP process may cause copper oxide (CuO) 110 to form on an upper portion of the copper material 106. The CMP process may also leave residues 112 on the structure 100, such as, for example, carbon containing compounds from a CMP slurry. The copper oxide 110 and CMP residues 112 can negatively affect the electrical conductivity of the copper material 106 and adhesion of subsequent layers formed on the structure 100.

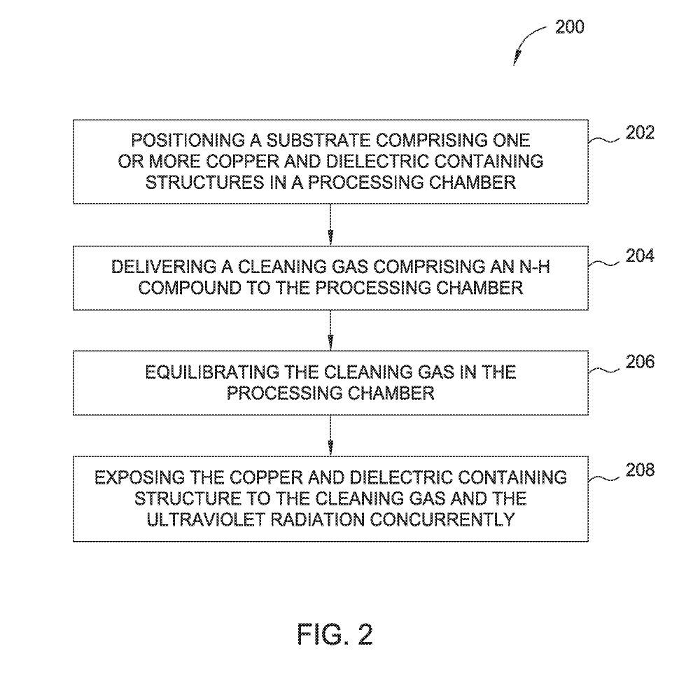

FIG. 2 is a flow diagram of a method 200 for removing copper oxides according to one embodiment. The method 200 begins at step 202 with a substrate comprising one or more copper and dielectric containing structures being positioned in a processing chamber. The process may be performed in an UV processing chamber, such as the NANOCURE™ chamber, coupled to the Producer® GT™ or Producer® SE systems commercially available from Applied Materials, Inc., located in Santa Clara, Calif. In one embodiment, the substrate is positioned in a processing volume of a processing chamber. It is to be understood that the chamber described above is an exemplary embodiment and other chambers, including chambers from the same or other manufacturers, may be used with or modified to match embodiments of this invention without diverging from the inventive characteristics described herein.

The substrate can be a substrate as described with reference to FIG. 1. Suitable substrate materials can include but are not limited to glass, quartz, sapphire, germanium, plastic or composites thereof. Additionally, the substrate can be a relatively rigid substrate or a flexible substrate. Further, any suitable substrate size may be processed. Examples of suitable substrate sizes include substrate having a surface area of about 2000 centimeter square or more, such as about 4000 centimeter square or more, for example about 10000 centimeter square or more. In one embodiment, the structure 100, described with reference to FIG. 1, is the substrate comprising one or more copper and dielectric containing structures.

Once the substrate is positioned in the processing chamber, a cleaning gas comprising an N—H compound is delivered to the processing chamber, as in step 204. The cleaning gas can then flow into the processing volume. The cleaning gas can include an N—H compound, an inert gas or combinations thereof. The N—H compound is a compound which comprises at least one N—H bond. Examples of the N—H compound usable with embodiments described herein can include ammonia (NH₃) and amino-containing compounds such as aminonitrite, hydroxylamine, methylamine and dimethylamine. The inert gas can be any non-reactive gas such as a noble gas, e.g. helium, argon, etc. In one embodiment, the cleaning gas comprises NH₃ and argon.

For a 300 mm diameter substrate, the method may be conducted at a chamber pressure between 10 milliTorr and 760 Torr, such as from 25 Torr to 100 Torr. In one embodiment, the chamber pressure is 50 Torr. The substrate temperature can be maintained between about 25° C. and about 400° C., such as between 200° C. and 400° C., In one embodiment, the substrate temperature is maintained at approximately 250° C. In another embodiment, the substrate temperature is maintained between about 100° C. and about 400° C. In another embodiment, the substrate temperature is maintained between about 150° C. and about 175° C. The N—H compound flow rate can be between 100 sccm and 30,000 sccm, such as 4000 sccm. In one embodiment, the N—H compound gas flow rate is between 100 sccm and 1000 sccm, such as 500 sccm. The cleaning gas flow rate can be the same ranges as described with reference to the N—H compound flow rate. The flow rates per mm² for the cleaning gas or the N—H compound can be between approximately 0.001414 sccm/mm² and 0.4244 sccm/mm², such as 0.05659 sccm/mm². In another embodiment, the flow rates per mm² for the cleaning gas or the N—H compound can be between approximately 0.001414 sccm/mm² and 0.01415 sccm/mm², such as 0.00707 sccm/mm².

The cleaning gas is then equilibrated in the processing chamber, as in step 206. It is believed to be important that the cleaning gas be equally available to the exposed surfaces prior to UV activation. It is known that ammonia plasma damages low k materials. Further, ammonia can be activated by UV radiation. As such, if higher concentrations of the ammonia are present in dielectric regions and lower concentrations are present near the copper oxide regions, damage may occur. By equilibrating the cleaning gas in the chamber prior to activation, a possible source of damage can be avoided.

Once the cleaning gas has equilibrated, the copper and dielectric containing structure can be exposed to the cleaning gas and the UV radiation concurrently. The UV irradiance power can be between 0.001 W/cm² and 20 W/cm², such as between 0.5 W/cm² and 5.0 W/cm². The UV wavelengths delivered to the substrate can be less than or equal to 400 nm, such as between 100 nm and 200 nm. In one embodiment, the UV wavelengths delivered to the substrate are from 180 nm to 200 nm. In one or more embodiments, the wavelengths delivered to the substrate are delivered as part of a broad band UV source such that one or more desired wavelengths are part of a spectrum delivered to the substrate simultaneously. The UV exposure time can be between 1 second and 900 seconds, such as 30 seconds.

Without intending to be bound by theory, the availability of free hydrogen from the N—H bonds is not believed to be temperature dependent, The bond energy of the N—H bond in the exemplary embodiment, NH₃, is approximately 4.51 eV. The photon energy delivered by the UV radiation at between 180 nm and 200 nm is approximately 6.20-6.89 eV. Since the absorption of the UV energy at this wavelength by NH₃ is high, the NH₃ bonds should be easily broken by UV energy alone. However, temperature is believed to be important in maintaining concentrations of NH₃ near the surface of the substrate. Therefore, the temperatures described above can maintain reactant at the interface without affecting the free hydrogen concentration.

The method described above removes the copper oxide 105 while not significantly increasing the k value of the interlayer dielectric 102. Further, the cleaning gas as activated by UV removes one or more carbon deposits, as can be accumulated from the CMP process.

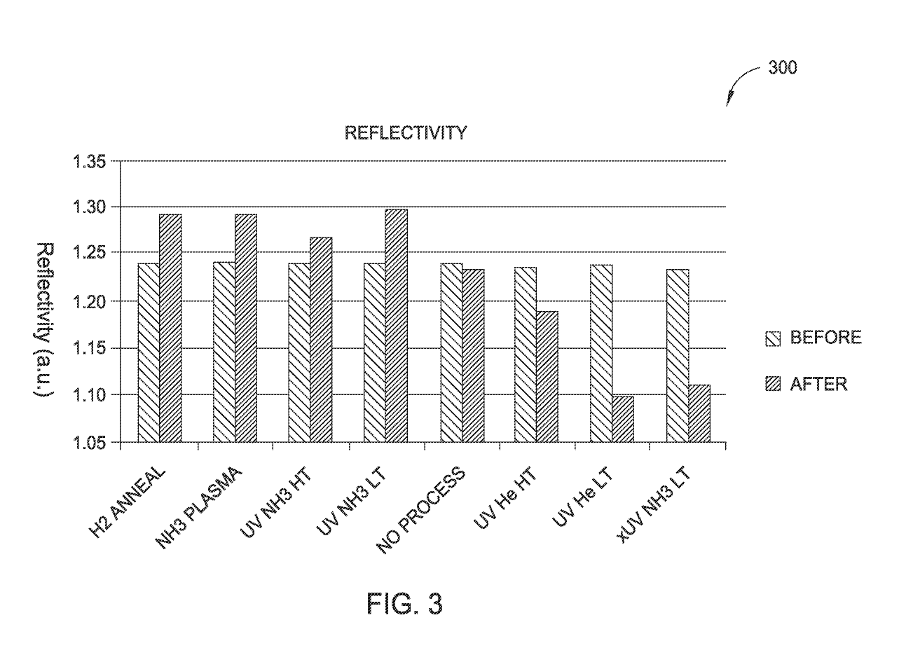

FIG. 3 is a chart 300 depicting copper removal based on reflectivity for a substrate processed according to one or more embodiments of the invention. The substrate with both copper and dielectric structures was treated with the experimental condition described. Reflectivity is measured in arbitrary units (a.u.). The substrate received 5 kÅ of undoped silicon glass, followed by a copper barrier seed (CuBS) layer. Over the CuBS layer, copper was deposited by electrochemical plating to 7 kÅ. Finally the structure was polished by CMP. The reflectivity described herein is reflection of 436 nm wavelength light from the surface of the substrate. 436 nm was used based on the difference in reflectivity between Cu and CuO at this wavelength.

The first column shows the reflectivity of a substrate both before and after a hydrogen anneal process. The reflectivity of the substrate before treatment was approximately 1.24 a.u. The reflectivity of the substrate after treatment was approximately 1.28 a.u.

The second column shows the reflectivity of a substrate both before and after an ammonia plasma process. The reflectivity of the substrate before treatment was approximately 1.24 a.u. The reflectivity of the substrate after treatment was approximately 1.28 a.u.

The third column shows the reflectivity of a substrate both before and after an ammonia UV exposure process. The ammonia UV exposure process was performed according to the method described above. In this embodiment, a high temperature was used, such as a temperature above 300° C. The reflectivity of the substrate before treatment was approximately 1.24 a.u. The reflectivity of the substrate after treatment was approximately 1.26 a.u.

The fourth column shows the reflectivity of a substrate both before and after an ammonia UV exposure process. The ammonia UV exposure process was performed according to the method described above. In this embodiment, a low temperature was used, such as a temperature below 300° C. The reflectivity of the substrate before treatment was approximately 1.24 a.u. The reflectivity of the substrate after treatment was approximately 1.29 a.u.

The fifth column shows the reflectivity of a substrate both before and after with no processing. The reflectivity of the substrate before treatment was approximately 1.24 a.u. The reflectivity of the substrate after treatment was approximately 1.24 a.u.

The sixth column shows the reflectivity of a substrate both before and after a helium UV exposure process. The helium UV exposure process was performed according to the method described above but without a N—H compound present. In this embodiment, a high temperature was used, such as a temperature above 300° C. The reflectivity of the substrate before treatment was approximately 1.24 a.u. The reflectivity of the substrate after treatment was approximately 1.18 a.u.

The seventh column shows the reflectivity of a substrate both before and after a helium UV exposure process. The helium UV exposure process was performed according to the method described above but without a N—H compound present. In this embodiment, a low temperature was used, such as a temperature below 300° C. The reflectivity of the substrate before treatment was approximately 1.24 a.u. The reflectivity of the substrate after treatment was approximately 1.09 a.u.

The eighth column shows the reflectivity of a substrate both before and after an ammonia exposure process. The ammonia exposure process was performed according to the method described above but without UV energy present. In this embodiment, a low temperature was used, such as a temperature below 300° C. The reflectivity of the substrate before treatment was approximately 1.24 a.u. The reflectivity of the substrate after treatment was approximately 1.11 a.u.

Thus, the graph 300 shows that both ammonia and UV in conjunction can provide CuO removal benefits which are the same or better than those seen using either H₂ anneal or NH₃ plasma processes.

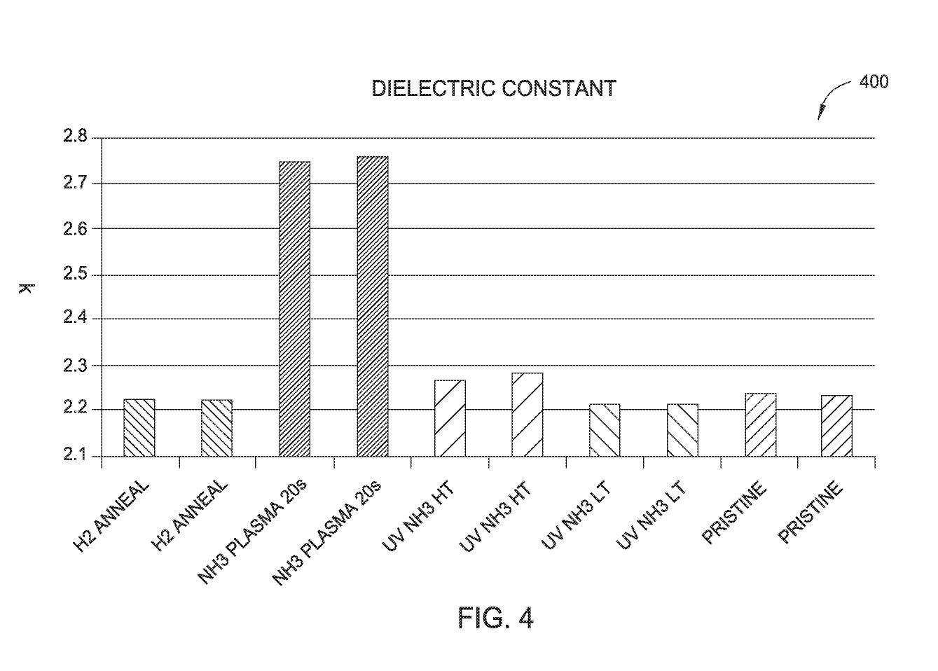

FIG. 4 is a chart 400 depicting damage to the dielectric structure during copper removal for a substrate processed according to one or more embodiments of the invention. The substrate with both copper and dielectric structures (a porous carbon-doped oxide) was treated with the experimental condition described. The dielectric constant k is shown on the y-axis. The substrate received 5 kÅ of undoped silicon glass, followed by a copper barrier seed (CuBS) layer. Over the CuBS layer, copper was deposited by electrochemical plating to 7 kÅ. Finally the structure was polished by CMP.

The first and second columns show the k value of the porous carbon-doped oxide on the substrate after a hydrogen anneal process. The first and second columns represent two separate test samples. The k value of the porous carbon-doped oxide in the first column was approximately 2.22. The k value of the porous carbon-doped oxide in the second column was approximately 2.21.

The third and fourth columns show the k value of the porous carbon-doped oxide on the substrate after an NH₃ plasma process. The NH₃ plasma was delivered to the substrate for 20 seconds. The third and fourth columns represent two separate test samples. The k value of the porous carbon-doped oxide in the first column was approximately 2.74. The k value of the porous carbon-doped oxide in the second column was approximately 2.75.

The fifth and sixth columns show the k value of the porous carbon-doped oxide on the substrate after an NH₃ UV exposure process. The ammonia UV exposure process was performed according to the methods described above. In this embodiment, a high temperature was used, such as a temperature above 300° C. The fifth and sixth columns represent two separate test samples. The k value of the porous carbon-doped oxide in the first column was approximately 2.37. The k value of the porous carbon-doped oxide in the second column was approximately 2.39.

The seventh and eighth columns show the k value of the porous carbon-doped oxide on the substrate after an NH₃ UV exposure process. The NH₃ UV exposure process was performed according to the methods described above. In this embodiment, a low temperature was used, such as a temperature below 300° C. The seventh and eighth columns represent two separate test samples. The k value of the porous carbon-doped oxide in the first column was approximately 2.21. The k value of the porous carbon-doped oxide in the second column was approximately 2.21.

The ninth and tenth columns show the k value of the porous carbon-doped oxide on the substrate after an NH₃ UV exposure process. The NH₃ UV exposure process was performed according to the methods described above. In this embodiment, a low temperature was used, such as a temperature below 300° C. The ninth and tenth columns represent two separate test samples. The k value of the porous carbon-doped oxide in the first column was approximately 2.23. The k value of the porous carbon-doped oxide in the second column was approximately 2.22.

As shown, the low temperature NH₃ UV exposure process shows no increase in k value for the dielectric layer. The high temperature NH₃ UV exposure process shows a slight increase in k value for the dielectric layer. The damage to the dielectric layer is reduced compared to that caused by the NH₃ plasma.

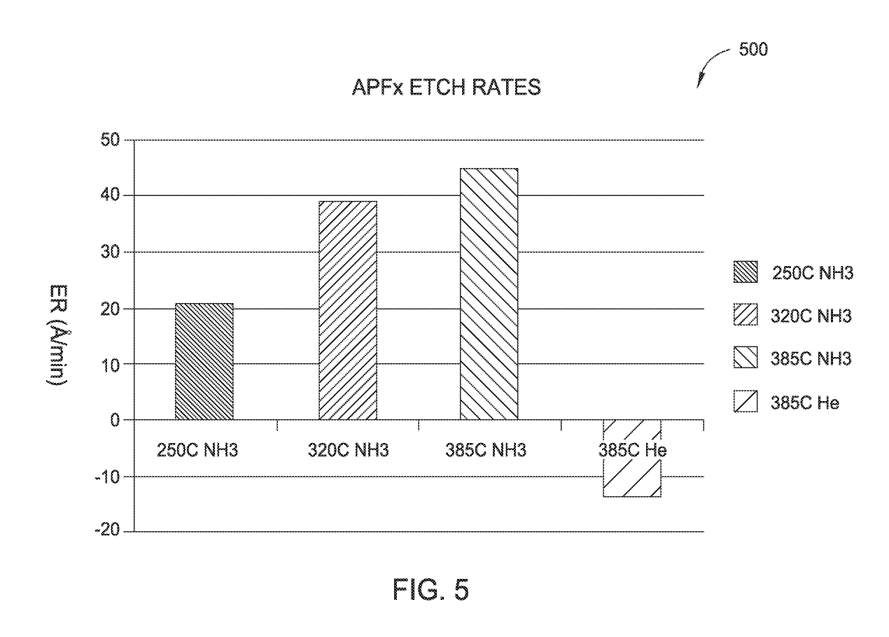

FIG. 5 is a chart 500 depicting the etch rate of a carbon containing layer for a substrate processed according to one or more embodiments of the invention. The chart 500 shows the etch rate under varying conditions using a substrate with APFx™ advanced patterning film (the carbon containing layer), available from Applied Materials, Inc. located in Santa Clara, Calif., deposited by PECVD. The etch rate is shown as Å/min on the y axis. The x-axis depicts the various conditions for processing.

The first column shows the etch rate of the carbon-containing layer on the substrate after a NH₃ UV exposure process at a temperature of 250° C. The NH₃ UV exposure process was performed according to the methods described above. The etch rate was approximately 21 Å/min.

The second column shows the etch rate of the carbon-containing layer on the substrate after a NH₃ UV exposure process at a temperature of 320° C. The NH₃ UV exposure process was performed according to the methods described above. The etch rate was approximately 38 Å/min.

The third column shows the etch rate of the carbon-containing layer on the substrate after a NH₃ UV exposure process at a temperature of 385° C. The NH₃ UV exposure process was performed according to the methods described above. The etch rate was approximately 45 Å/min.

The fourth column shows the etch rate of the carbon-containing layer on the substrate after a helium UV exposure process at a temperature of 385° C. The helium UV exposure process was performed according to the methods described above. No etching was detected in the layer.

Therefore, the NH₃ UV exposure process described above resulted in a measurable etch rate of the carbon containing layer. Therefore, the NH₃ UV exposure process can be effectively used to remove carbon deposits simultaneously with the removal of oxides from the copper surfaces.

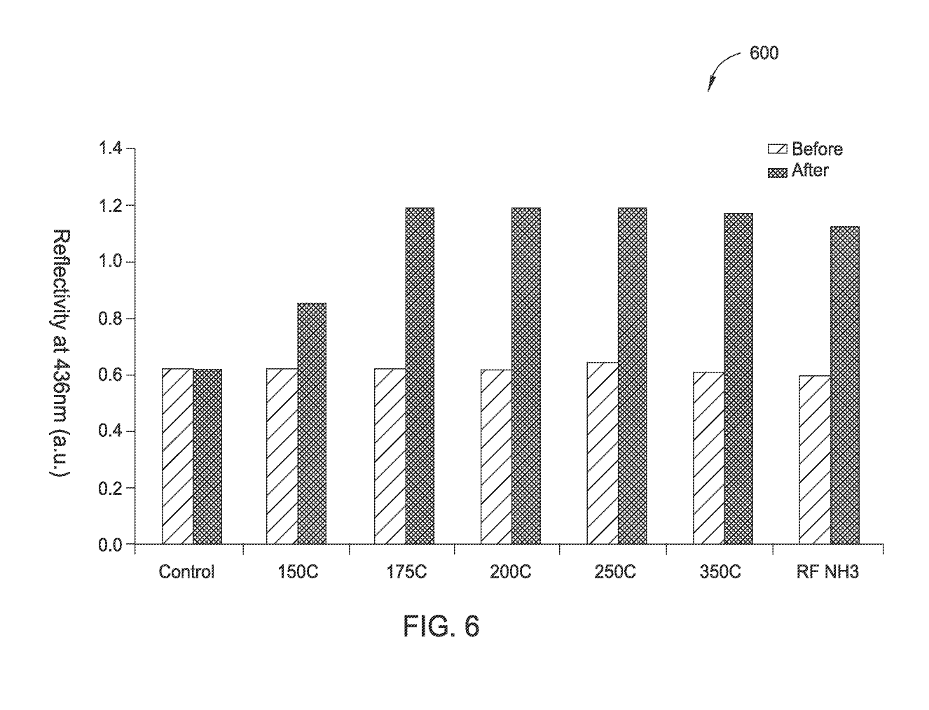

FIG. 6 is a chart 600 depicting copper oxide removal based on reflectivity for a substrate processed according to one or more embodiments of the invention. The substrate with both copper and dielectric structures was treated with the experimental condition described, Reflectivity is measured in arbitrary units (a.u.). The substrate received 5 kÅ of undoped silicon glass, followed by a copper barrier seed (CuBS) layer. Over the CuBS layer, copper was deposited by electrochemical plating to 7 kÅ. Finally the structure was polished by CMP.

The polished substrate was then processed for CuO removal. The process conditions included delivering NH₃ at 500 sccm. The process chamber was maintained at a pressure of 50 Torr and the temperature was varied as shown in the graph 600. UV was delivered at 90% maximum power over a process time of 30 seconds, after which the reflectivity was measured. The reflectivity described herein is reflection of 436 nm wavelength light from the surface of the substrate.

The first column shows the reflectivity of a substrate both before and after a control NH₃ anneal process. The temperature was maintained at an ambient temperature (approximately 25° C.). The reflectivity of the substrate before treatment was approximately 0.62 a.u. The reflectivity of the substrate after treatment was approximately 0.60 a.u.

The second column shows the reflectivity of a substrate both before and after a NH₃ anneal process with a temperature of approximately 150° C. The reflectivity of the substrate before treatment was approximately 0.62 a.u. The reflectivity of the substrate after treatment was approximately 0.86 a.u.

The third column shows the reflectivity of a substrate both before and after a NH₃ anneal process with a temperature of approximately 175° C. The reflectivity of the substrate before treatment was approximately 0.62 a.u. The reflectivity of the substrate after treatment was approximately 1.20 a.u.

The fourth column shows the reflectivity of a substrate both before and after a NH₃ anneal process with a temperature of approximately 200° C. The reflectivity of the substrate before treatment was approximately 0.62 a.u. The reflectivity of the substrate after treatment was approximately 1.20 a.u.

The fifth column shows the reflectivity of a substrate both before and after a NH₃ anneal process with a temperature of approximately 250° C. The reflectivity of the substrate before treatment was approximately 0.64 a.u. The reflectivity of the substrate after treatment was approximately 1.20 a.u.

The sixth column shows the reflectivity of a substrate both before and after a NH₃ anneal process with a temperature of approximately 350° C. The reflectivity of the substrate before treatment was approximately 0.62 a.u. The reflectivity of the substrate after treatment was approximately 1.20 a.u.

The seventh column shows the reflectivity of a substrate both before and after a NH₃ anneal process with RF power at an ambient temperature (approximately 25° C.). The reflectivity of the substrate before treatment was approximately 0.62 a.u. The reflectivity of the substrate after treatment was approximately 1.17 a.u.

Thus, the graph 600 shows that a lower heating temperature, such as 175° C. can provide CuO removal benefits which are similar to those provided at higher temperatures, such as 250° C.

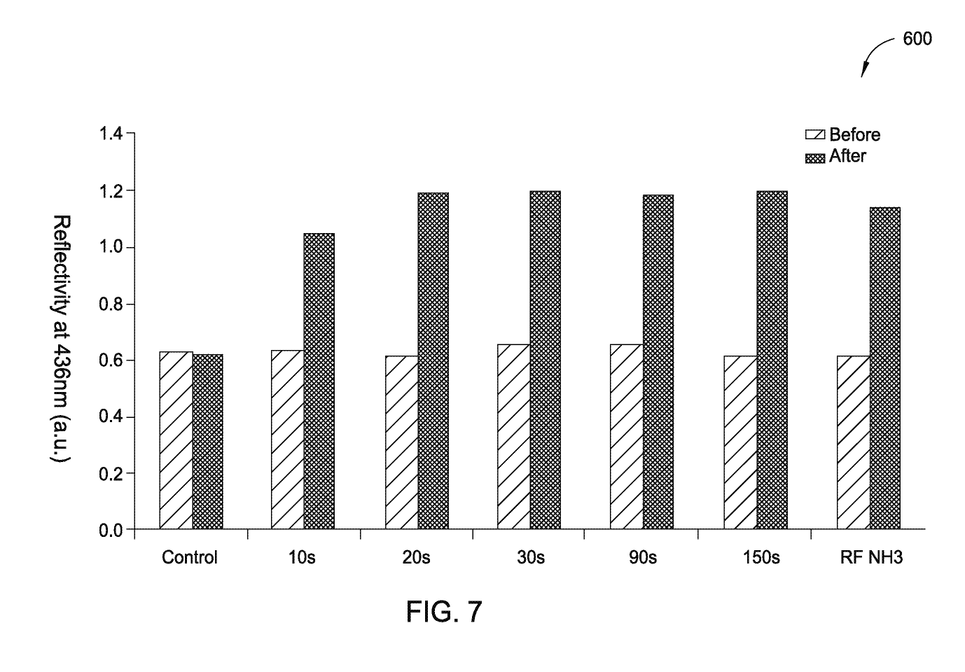

FIG. 7 is a chart 700 depicting copper oxide removal based on reflectivity for a substrate processed according to one or more embodiments of the invention. The substrate with both copper and dielectric structures was treated with the experimental condition described. Reflectivity is measured in arbitrary units (a.u.). The substrate received 5 kÅ of undoped silicon glass, followed by a copper barrier seed (CuBS) layer. Over the CuBS layer, copper was deposited by electrochemical plating to 7 kÅ. Finally the structure was polished by CMP.

The polished substrate was then processed for CuO removal. The process conditions included delivering NH₃ at 500 sccm. The process chamber was maintained at a pressure of 50 Torr, the temperature was 250° C. and the process time varied as shown in the graph 700. UV was delivered at 90% maximum power, after which the reflectivity was measured. The reflectivity described herein is reflection of 436 nm wavelength light from the surface of the substrate.

The first column shows the reflectivity of a substrate both before and after a control NH₃ anneal process. The process conditions were provided but without NH₃ flow or UV. The reflectivity of the substrate before treatment was approximately 0.62 a.u. The reflectivity of the substrate after treatment was approximately 0.60 a.u.

The second column shows the reflectivity of a substrate both before and after a NH₃ anneal process with a process time of approximately 10 seconds. The reflectivity of the substrate before treatment was approximately 0.62 a.u. The reflectivity of the substrate after treatment was approximately 1.05 a.u.

The third column shows the reflectivity of a substrate both before and after a NH₃ anneal process with a process time of approximately 20 seconds. The reflectivity of the substrate before treatment was approximately 0.60 a.u. The reflectivity of the substrate after treatment was approximately 1.20 a.u.

The fourth column shows the reflectivity of a substrate both before and after a NH₃ anneal process with a process time of approximately 30 seconds. The reflectivity of the substrate before treatment was approximately 0.62 a.u. The reflectivity of the substrate after treatment was approximately 1.20 a.u.

The fifth column shows the reflectivity of a substrate both before and after a NH₃ anneal process with a process time of approximately 90 seconds. The reflectivity of the substrate before treatment was approximately 0.62 a.u. The reflectivity of the substrate after treatment was approximately 1.17 a.u.

The sixth column shows the reflectivity of a substrate both before and after a NH₃ anneal process with a process time of approximately 150 seconds. The reflectivity of the substrate before treatment was approximately 0.60 a.u. The reflectivity of the substrate after treatment was approximately 1.20 a.u.

The seventh column shows the reflectivity of a substrate both before and after a NH₃ anneal process with RF power at an ambient temperature (approximately 25° C.). The reflectivity of the substrate before treatment was approximately 0.62 a.u. The reflectivity of the substrate after treatment was approximately 1.17 a.u.

Thus, the graph 600 shows that a shorter time frame, such as 20 seconds can provide CuO removal benefits which are similar to those provided for longer time frames, such as 30 seconds.

While the foregoing is directed to embodiments of the present invention, other and further embodiments of the invention may be devised without departing from the basic scope thereof, and the scope thereof is determined by the claims that follow.

1. A method for removing copper oxides comprising:
positioning a substrate in a processing chamber, the substrate comprising one or more copper containing structures and one or more dielectric containing structures;
delivering a cleaning gas comprising nitrogen-containing compound to the processing chamber, the nitrogen-containing compound having an N—H bond; and
exposing the copper containing structures and the dielectric containing structures to the cleaning gas and ultraviolet (UV) radiation concurrently.

2. The method of claim 1, further comprising planarizing the substrate using chemical mechanical polishing prior to positioning in the processing chamber.

3. The method of claim 1, wherein the substrate is maintained at a temperature between 100° C. and 400° C.

4. The method of claim 1, wherein the cleaning gas equilibriates throughout the chamber prior to exposing the copper containing structures and the dielectric containing structures to UV radiation.

5. The method of claim 1, wherein the UV radiation is delivered at a power between 0.001 W/cm² and 20 W/cm².

6. The method of claim 1, wherein the photon energy of the UV radiation is higher than the energy of the N—H bond in the nitrogen-containing compound.

7. The method of claim 1, wherein the N—H compound is ammonia.

8. A method for removing copper oxides comprising:
planarizing a substrate, the substrate comprising one or more copper containing structure and one or more dielectric containing structures;
positioning the substrate in a processing chamber;
maintaining the substrate at a temperature between 200° C. and 400° C.;
delivering a cleaning gas to the processing chamber, the cleaning gas comprising a nitrogen-containing gas having an N—H bond;
equilibrating the cleaning gas in the processing chamber; and
exposing the copper and dielectric containing structure to the cleaning gas and ultraviolet (UV) radiation concurrently, wherein the wavelength is between 180 nm and 200 nm.

9. The method of claim 8, wherein the substrate is maintained at a temperature between 200° C. and 400° C.

10. The method of claim 8, wherein the UV radiation is delivered at a power between 0.001 W/cm² and 20 W/cm².

11. The method of claim 8, wherein the photon energy of the UV radiation is higher than the energy of the N—H bond in the nitrogen-containing gas.

12. A method for removing copper oxides comprising:
heating a substrate positioned in a processing chamber to a first temperature, the first temperature being between 200° C. and 400° C.;
delivering a cleaning gas to the substrate, the cleaning gas comprising ammonia, the substrate comprising one or more copper surfaces and one or more dielectric containing structures;
delivering UV radiation at a power of between 0.001 W/cm² and 20 W/cm² to the cleaning gas and the substrate, wherein the UV radiation activates the cleaning gas; and
removing copper oxides from the one or more copper surfaces using the activated cleaning gas.

13. The method of claim 12, further comprising planarizing the substrate using chemical mechanical polishing prior to positioning in the processing chamber

14. The method of claim 12, wherein the cleaning gas equilibriates throughout the chamber prior to exposing the substrate to UV radiation.

15. The method of claim 12, wherein the photon energy of the UV radiation is higher than the energy of the N—H bond in the ammonia of the cleaning gas.

16. The method of claim 8, wherein the cleaning gas equilibriates throughout the chamber prior to exposing the copper and the dielectric containing structure to UV radiation.

17. The method of claim 12, wherein the UV radiation is radiation of a wavelength between 180 nm and 200 nm.

18. The method of claim 1, wherein the UV radiation contains a plurality of wavelengths, the wavelengths being delivered to the substrate as part of a broad band UV source such that plurality of wavelengths are part of a spectrum delivered to the substrate simultaneously.

19. The method of claim 8, wherein the UV radiation contains a plurality of wavelengths, the wavelengths being delivered to the substrate as part of a broad band UV source such that plurality of wavelengths are part of a spectrum delivered to the substrate simultaneously.

20. The method of claim 8, wherein the UV radiation contains a plurality of wavelengths, the wavelengths being delivered to the substrate as part of a broad band UV source such that plurality of wavelengths are part of a spectrum delivered to the substrate simultaneously.
